(19) United States
(12) Patent Application Publication
(10) Pub. No.: US 2025/0214324 A1
(43) Pub. Date: Jul. 3, 2025

(54) CERAMIC SUBSTRATE AND METHOD FOR MANUFACTURING CERAMIC SUBSTRATE

(71) Applicant: Murata Manufacturing Co., Ltd., Nagaokakyo-shi (JP)

(72) Inventors: Atsushi KISHIMOTO, Nagaokakyo-shi (JP); Tomoki KATO, Nagaokakyo-shi (JP); Masato INAOKA, Nagaokakyo-shi (JP); Hiroshi NISHIKAWA, Nagaokakyo-shi (JP)

(21) Appl. No.: 19/055,830

(22) Filed: Feb. 18, 2025

Related U.S. Application Data
(63) Continuation of application No. PCT/JP2023/033191, filed on Sep. 12, 2023.

(30) Foreign Application Priority Data
Sep. 20, 2022 (JP) 2022-149093

(51) Int. Cl. B32B 18/00; B32B 3/10; B32B 3/26; B32B 3/30; B32B 37/06; H05K 1/02; H05K 3/12; H05K 3/46

(52) U.S. Cl. CPC B32B 18/00; B32B 3/10; B32B 3/266; B32B 3/30; B32B 37/06; H05K 1/0206; H05K 1/0207; H05K 1/0298; H05K 3/1283; H05K 3/4697; B32B 2307/302; B32B 2307/7376; B32B 2457/08; C04B 2237/56; C04B 2237/62; C04B 2237/64; H05K 2201/068; H05K 2203/1126

(57) ABSTRACT

A ceramic substrate includes a multilayer body including stacked ceramic layers and a housing portion in an interior of the multilayer body and a heat dissipation portion in the housing portion. A first hollow is provided between at least a portion of an outer surface of the heat dissipation portion and an inner wall surface of the housing portion in an extension direction of the heat dissipation portion.

### CROSS REFERENCE TO RELATED APPLICATIONS

This application claims the benefit of priority to Japanese Patent Application No. 2022-149093 filed on Sep. 20, 2022 and is a Continuation Application of PCT Application No. PCT/JP2023/033191 filed on Sep. 12, 2023. The entire contents of each application are hereby incorporated herein by reference.

### BACKGROUND OF THE INVENTION

### 1. Field of the Invention

The present invention relates to ceramic substrates and methods for manufacturing ceramic substrates.

### 2. Description of the Related Art

Electronic-component-mounted multilayer substrates in which electronic components are mounted on a multilayer circuit substrate are required to have high heat dissipation performance in accordance with size reduction, high integration, speeding up, and the like of electronic components.

Regarding the electronic device including a substrate having high heat dissipation performance, Japanese Unexamined Patent Application Publication No. 2010-080572 discloses an electronic device including a multilayer substrate (10) in which a plurality of layers (1 to 6) are stacked and a heat generation element (20) disposed on one surface (11) of the multilayer substrate (10), wherein a heat diffusion layer (15) that has thermal conductivity and that is thinner than each of the layers (1 to 6) is disposed between the adjoining layers (1 to 6) in the interior of the multilayer substrate (10), and a heat dissipation via (14) that is disposed extending in the stacking direction of the layers (1 to 6) and that thermally couples the heat generation element (20) to the heat diffusion layer (15) is disposed in the interior of the multilayer substrate (10).

With the multilayer substrate (10) in the electronic device described in Japanese Unexamined Patent Application Publication No. 2010-080572, since the heat dissipation layer (15) is provided and the heat dissipation layer (15) is thermally coupled to the heat generation element (20) through the heat dissipation via (14), the heat from the heat generation element (20) can be efficiently emitted to the outside.

When a multilayer substrate (ceramic substrate) in which layers (ceramic layers) including a heat diffusion layer (heat dissipation portion) in the interior are stacked, as described in Japanese Unexamined Patent Application Publication No. 2010-080572, is produced, and an electronic device is produced by using the multilayer substrate (ceramic substrate), a thermal shock is applied to the multilayer substrate (ceramic substrate) due to firing, reflow treatment, or the like. When such a thermal shock is applied, defects, such as a crack, tend to occur in the heat diffusion layer (heat dissipation portion) and the layer (ceramic layer), and defects, such as a crack and interfacial peeling, tend to occur in the vicinity of the interface between the heat diffusion layer (heat dissipation portion) and the layer (ceramic layer).

In addition, even when defects, such as a crack, do not occur in the heat diffusion layer (heat dissipation portion) and the layer (ceramic layer), and defects do not occur in the vicinity of the interface between the heat diffusion layer (heat dissipation portion) and the layer (ceramic layer) during production, defects, such as a crack, may occur in the heat diffusion layer (heat dissipation portion) and the layer (ceramic layer), and defects may occur in the vicinity of the interface between the heat diffusion layer (heat dissipation portion) and the layer (ceramic layer) due to the heat from the heat generation element (heat generation component) being repeatedly applied.

When such a defect occurs, there is a problem that the substrate flexural strength of the multilayer substrate (ceramic substrate) deteriorates.

### SUMMARY OF THE INVENTION

Example embodiments of the present invention provide ceramic substrates each able to, even when a thermal shock is applied, reduce or prevent a defect from occurring in a heat dissipation portion and a ceramic layer, reduce or prevent a defect from occurring in the vicinity of the interface between the heat dissipation portion and the ceramic layer, and reduce or prevent the substrate flexural strength of the ceramic substrate from deteriorating and provide methods for manufacturing such ceramic substrates.

The inventors of example embodiments of the present invention have discovered that the cause of a defect in the heat dissipation portion and the ceramic layer and a defect in the vicinity of the interface between the heat dissipation portion and the ceramic layer is due to the thermal stress generated in the heat dissipation portion not being reduced or relieved. Further, it was discovered that the above-described problems are addressed by reducing or relieving the thermal stress.

A ceramic substrate according to an example embodiment of the present invention includes a multilayer body including a plurality of stacked ceramic layers and a housing portion in an interior of the multilayer body, and a heat dissipation portion in the housing portion, wherein a first hollow is provided between at least a portion of an outer surface of the heat dissipation portion and an inner wall surface of the housing portion in an extension direction of the heat dissipation portion.

In addition, a method for manufacturing a ceramic substrate according to an example embodiment of the present invention includes preparing an unfired multilayer body including a ceramic green sheet multilayer body that includes a plurality of stacked ceramic green sheets and a hole portion in an interior, and a heat dissipation portion in the hole portion and producing a ceramic substrate in which the heat dissipation portion is arranged in a housing portion by firing the unfired multilayer body to convert the ceramic green sheet to a ceramic layer and to convert the hole portion to the housing portion, wherein, the firing is performed so that the housing portion formed through the firing has a size in which a first hollow is formed between at least a portion of an outer surface of the heat dissipation portion and an inner wall surface of the housing portion in an extension direction of the heat dissipation portion of the ceramic substrate produced through the firing.

According to example embodiments of the present invention, ceramic substrates capable of, even when a thermal shock is applied, reducing or preventing a defect from occurring in a heat dissipation portion and a ceramic layer, reducing or preventing a defect from occurring in the vicinity of the interface between the heat dissipation portion and the ceramic layer, and reducing or preventing the substrate flexural strength of the ceramic substrate from deteriorating, and methods for manufacturing such ceramic substrates are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a schematic sectional view illustrating an example of a ceramic substrate according to an example embodiment of the present invention.

FIG. 1B is an enlarged diagram illustrating a broken line portion in FIG. A.

FIG. 1C is a sectional view illustrating the section taken along line A-A in FIG. 1B.

FIG. 2A is an enlarged schematic sectional view illustrating an example of a section of another ceramic substrate according to an example embodiment of the present invention when cut passing a heat dissipation portion in an extension direction of the heat dissipation portion.

FIG. 2B is an enlarged schematic sectional view illustrating an example of a section of another ceramic substrate according to an example embodiment of the present invention when cut passing a heat dissipation portion in an extension direction of the heat dissipation portion.

FIG. 2C is an enlarged schematic sectional view illustrating an example of a section of another ceramic substrate according to an example embodiment of the present invention when cut passing a heat dissipation portion in an extension direction of the heat dissipation portion.

FIG. 2D is an enlarged schematic sectional view illustrating an example of a section of another ceramic substrate according to an example embodiment of the present invention when cut passing a heat dissipation portion in an extension direction of the heat dissipation portion.

FIG. 2E is an enlarged schematic sectional view illustrating an example of a section of another ceramic substrate according to an example embodiment of the present invention when cut passing a heat dissipation portion in an extension direction of the heat dissipation portion.

FIG. 3A is a schematic sectional view illustrating an example of the vicinity of a heat dissipation portion in another ceramic substrate according to an example embodiment of the present invention.

FIG. 3B is a schematic sectional view illustrating an example of the vicinity of a heat dissipation portion in another ceramic substrate according to an example embodiment of the present invention.

FIG. 4A is a schematic sectional view illustrating an example of a ceramic green sheet preparation sub-step in a method for manufacturing a ceramic substrate according to an example embodiment of the present invention.

FIG. 4B is a schematic sectional view illustrating an example of a hole portion via hole formation sub-step in a method for manufacturing a ceramic substrate according to an example embodiment of the present invention.

FIG. 4C is a schematic sectional view illustrating an example of an electrically conductive paste arrangement sub-step in a method for manufacturing a ceramic substrate according to an example embodiment of the present invention.

FIG. 4D is a schematic sectional view illustrating an example of a constraining layer preparation sub-step in a method for manufacturing a ceramic substrate according to an example embodiment of the present invention.

FIG. 4E is a schematic sectional view illustrating an example of a ceramic green sheet stacking sub-step in a method for manufacturing a ceramic substrate according to an example embodiment of the present invention.

FIG. 5A is a schematic sectional view illustrating an example of a firing step in a method for manufacturing a ceramic substrate according to an example embodiment of the present invention.

FIG. 5B is a schematic sectional view illustrating an example of a ceramic substrate including a constraining layer after the firing step in a method for manufacturing a ceramic substrate according to an example embodiment of the present invention.

### DETAILED DESCRIPTION OF THE EXAMPLE EMBODIMENTS

Ceramic substrates and methods for manufacturing ceramic substrates according to example embodiments of the present invention will be described below with reference to the drawings.

However, the present invention is not limited to the configurations described below and the configurations can be appropriately modified and applied within scope of the present invention. In this regard, the present invention also includes combinations of at least two of example embodiments of the present invention described below.

A ceramic substrate according to an example embodiment of the present invention includes a multilayer body that includes a plurality of stacked ceramic layers and a housing portion in an interior and a heat dissipation portion arranged in the housing portion, wherein a first hollow is provided between at least a portion of an outer surface of the heat dissipation portion and an inner wall surface of the housing portion in an extension direction of the heat dissipation portion.

Ceramic substrates according to example embodiments of the present invention may have any configurations within the bounds of providing advantageous effects of the present invention provided that the above-described configurations are provided.

Each of the example embodiments described below is an exemplification and configurations described in different example embodiments can be partially replaced or combined with each other. In particular, regarding the same or similar operations and advantages due to the same or similar configuration, explanations will not be provided with respect to each example embodiment.

In this regard, for the sake of facilitating explanations, the drawings used for the following explanations are schematic drawings, and scales and details are different from that of actual products.

### EXAMPLE EMBODIMENT

A ceramic substrate according to an example embodiment of the present invention will be described in detail with reference to the drawings.

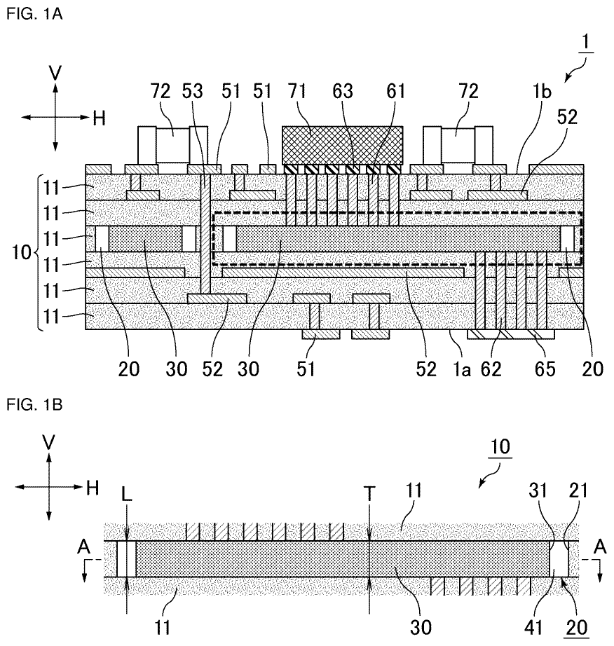

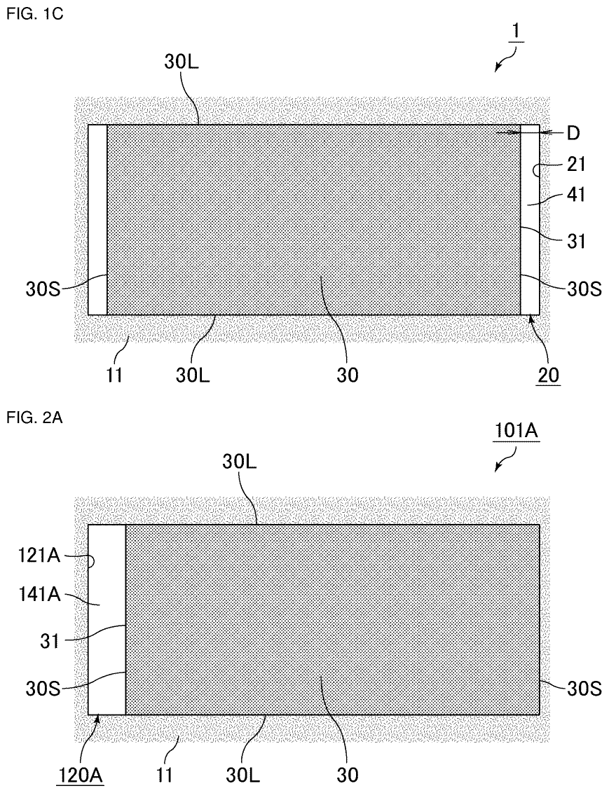

FIG. 1A is a schematic sectional view illustrating an example of a ceramic substrate according to an example embodiment of the present invention.

FIG. 1B is an enlarged diagram illustrating a broken line portion in FIG. A.

FIG. 1C is a sectional view illustrating the section taken along line A-A in FIG. 1B.

A ceramic substrate 1 illustrated in FIG. 1A includes a multilayer body 10 that includes a plurality of stacked ceramic layers 11 and a housing portion 20 in an interior and a sheet-shaped heat dissipation portion 30 provided in the housing portion 20.

A plurality of surface electrodes 51 are disposed on the surface of the ceramic substrate 1, and a plurality of inner conductors 52 are disposed in the interior. The surface electrode 51 is electrically coupled to the inner conductor 52 through a wiring via 53. In this regard, although not illustrated in FIG. 1A, the inner conductors 52 may be electrically coupled to each other through the wiring via 53 in the ceramic substrate 1.

As illustrated in FIG. 1A, an outer heat dissipation portion 65 is arranged on one principal surface 1a of the ceramic substrate 1.

In addition, a heat generation component 71 and a passive component 72 are arranged on the other principal surface 1b of the ceramic substrate 1.

In the ceramic substrate 1, a first heat dissipation via 61 that penetrates a ceramic layer 11 located between the heat generation component 71 and the heat dissipation portion 30 and that connects the heat generation component 71 to the heat dissipation portion 30 is provided. In addition, a heat dissipation pad 63 is disposed between the heat generation component 71 and the first heat dissipation via 61. In this regard, although not illustrated in FIG. 1A, the heat generation component 71 is also connected to the surface electrode.

In addition, in the ceramic substrate 1, a second heat dissipation via 62 that penetrates the ceramic layer 11 located between the heat dissipation portion 30 and the outer heat dissipation portion 65 and that connects the heat dissipation portion 30 to the outer heat dissipation portion 65 is provided. In this regard, although not illustrated in FIG. 1A, a heat dissipation pad may be provided between the outer heat dissipation portion 65 and the second heat dissipation via 62.

Regarding the ceramic substrate 1, the heat generated in the heat generation component 71 is transferred to the outer heat dissipation portion 65 through the first heat dissipation via 61, the heat dissipation portion 30, and the second heat dissipation via 62 so as to be emitted to the outside.

Since the ceramic substrate 1 includes the heat dissipation portion 30, the heat generated in the heat generation component 71 is promptly emitted to the outside. Consequently, the temperature of the heat generation component 71 and its surroundings is not readily increased. Therefore, even when the passive component 72 that is weak against heat is arranged near the heat generation component 71, the passive component 72 is not readily influenced by the heat generated in the heat generation component 71. As a result, the passive component 72 that is weak against heat can be arranged near the heat generation component 71.

As illustrated in FIG. 1B, in the ceramic substrate 1, a first hollow 41 is provided between an outer surface 31 of the heat dissipation portion 30 and an inner wall surface 21 of the housing portion 20 in an extension direction of the heat dissipation portion 30 (direction indicated by arrow H in FIG. 1B).

In this regard, in the stacking direction of the multilayer body 10 (direction indicated by arrow V in FIG. 1B), the outer surface 31 of the heat dissipation portion 30 is in contact with the inner wall surface 21 of the housing portion 20. That is, the upper surface and the bottom surface of the heat dissipation portion 30 are in contact with the inner wall surface 21 of the housing portion 20.

In the present specification, “extension direction of the heat dissipation portion” means the direction along a plane of a sheet when the heat dissipation portion has the shape of a sheet and means the major axis direction when the heat dissipation portion has the shape of a rod or a rugby ball.

As illustrated in FIG. 1B, in the ceramic substrate 1, the extension direction H of the heat dissipation portion 30 is in a direction perpendicular or substantially perpendicular to the stacking direction V.

In the ceramic substrate 1, the length L of the first hollow 41 is the same or substantially the same dimension as the thickness T of the heat dissipation portion 30 in the stacking direction V.

As illustrated in FIG. 1C, in the ceramic substrate 1, the heat dissipation portion 30 is rectangular or substantially rectangular in plan view and has the shape of a sheet.

Therefore, the extension direction H of the heat dissipation portion 30 means all directions perpendicular or substantially perpendicular to the stacking direction V.

In addition, as illustrated in FIG. 1C, the outline of the housing portion 20 is also rectangular or substantially rectangular in plan view.

In FIG. 1C, the first hollow 41 is provided between the outer surface 31 located on both short side portions 30S of the heat dissipation portion 30 and the inner wall surface 21 of the housing portion 20.

In this regard, the outer surface 31 located on both long side portions 30L of the heat dissipation portion 30 are in contact with the inner wall surface 21 of the housing portion 20.

In the ceramic substrate 1, the distance D from the outer surface 31 of the heat dissipation portion 30 to the inner wall surface 21 of the housing portion 20 (that is, the length of the first hollow 41) is, for example, preferably about 0.5 μm or more and about 200 μm or less and more preferably about 1 μm or more and about 100 μm or less.

The ceramic substrate 1 undergoes a thermal shock due to firing during production of the ceramic substrate 1 and reflow treatment during arrangement of the electronic components, such as the heat generation component 71 and the passive component 72, on the ceramic substrate 1.

Consequently, thermal stress is generated in the heat dissipation portion 30 and the ceramic layer 11.

When the ceramic substrate 1 undergoes a thermal shock, in general, since the coefficient of linear expansion of the heat dissipation portion 30 is larger than the coefficient of linear expansion of the ceramic layer 11, a difference occurs between the coefficient of expansion of the heat dissipation portion 30 and the coefficient of expansion of the ceramic layer 11. Consequently, thermal stress is generated in the heat dissipation portion 30 or at the interface between the heat dissipation portion 30 and the ceramic layer 11.

In addition, thermal stress is also generated in the heat dissipation portion 30 and the ceramic layer 11 and at the interface between the heat dissipation portion 30 and the ceramic layer 11 when heat is repeatedly applied from the heat generation component 71.

Herein, the reason for a defect in the heat dissipation portion and the ceramic layer and the reason for a defect in the vicinity of the interface between the heat dissipation portion and the ceramic layer when the first hollow is not provided in the ceramic substrate, that is, when the heat dissipation portion is fit in the housing portion, will be described.

When the ceramic substrate undergoes a thermal shock, the heat dissipation portion tends to thermally expand. When the hollow is not provided in the ceramic substrate, the heat dissipation portion cannot thermally expand, and thermal stress is generated in the interior of the heat dissipation portion. In addition, when the ceramic substrate undergoes a thermal shock, the ceramic substrate also thermally expands, and thermal stress is generated. The thermal stress causes a defect, such as a crack, in the heat dissipation portion and the ceramic layer.

Further, when a thermal shock is applied, since the coefficient of linear expansion of the heat dissipation portion differs from the coefficient of linear expansion of the ceramic layer, the heat dissipation portion and the ceramic layer do not uniformly thermally expand. Consequently, a difference in the thermal expansion occurs at the interface between the heat dissipation portion and the ceramic layer, and as a result, thermal stress is generated at the interface between the heat dissipation portion and the ceramic layer so that defects, such as a crack and interfacial peeling, tend to occur in the vicinity of the interface between the heat dissipation portion and the ceramic layer.

Such a defect causes deterioration of the substrate flexural strength of the ceramic substrate.

In this regard, when “interfacial peeling” occurs, a fine crack or deformation occurs in the heat dissipation portion or the ceramic layer.

On the other hand, as described later, the first hollow 41 of the ceramic substrate 1 is provided so that the heat dissipation portion 30 is not in contact with the ceramic layer 11. Consequently, neither a fine crack nor deformation due to interfacial peeling occurs in the heat dissipation portion 30 and the ceramic layer 11. Therefore, the state after the interface is peeled can be distinguished from the first hollow 41.

Whether there is a fine crack or deformation due to interfacial peeling can be determined by, for example, observing a scanning electron microscope (SEM) image of a cross section of the ceramic substrate.

On the other hand, since the first hollow 41 is provided in the ceramic substrate 1, the heat dissipation portion 30 can thermally expand toward the first hollow 41.

Consequently, the thermal stress generated in the heat dissipation portion 30 and the thermal stress generated at the interface between the heat dissipation portion 30 and the ceramic layer 11 can be reduced.

As a result, a defect in the heat dissipation portion 30 and the ceramic layer 11 and a defect in the vicinity of the interface between the heat dissipation portion 30 and the ceramic layer 11 do not readily occur.

That is, even when a thermal shock is applied, the ceramic substrate 1 is a ceramic substrate in which a defect does not readily occur in the heat dissipation portion 30 and the ceramic layer 11 and in which a defect does not readily occur in the vicinity of the interface between the heat dissipation portion 30 and the ceramic layer 11 and is a ceramic substrate having substrate flexural strength that does not readily deteriorate.

As described above, in the ceramic substrate 1, the outer surface 31 of the heat dissipation portion 30 is in contact with the inner wall surface 21 of the housing portion 20 in the stacking direction V. That is, the upper surface and the bottom surface of the heat dissipation portion 30 are in contact with the inner wall surface 21 of the housing portion 20.

In the ceramic substrate 1, it is preferable that no chemical bond due to mutual diffusion is present in a contact portion between the outer surface 31 of the heat dissipation portion and the inner wall surface 21 of the housing portion 20.

When a chemical bond due to mutual diffusion is present in a contact portion between the outer surface of the heat dissipation portion and the inner wall surface of the housing portion, during thermal expansion of the heat dissipation portion, the above-described chemical bond functions as resistance, and thermal stress tends to be generated at the interface between the heat dissipation portion and the ceramic layer. As a result, a defect tends to occur in the vicinity of the interface between the heat dissipation portion and the ceramic layer.

However, when the above-described chemical bond is not present, the heat dissipation portion 30 readily thermally expands so that thermal stress is not readily generated at the interface between the heat dissipation portion 30 and the ceramic layer 11. In the ceramic substrate 1 illustrated in FIG. 1C, the first hollow 41 is provided between the outer surface 31 located on both short side portions 30S of the heat dissipation portion 30 and the inner wall surface 21 of the housing portion 20. In this regard, the outer surface 31 located on both long side portions 30L of the heat dissipation portion 30 are in contact with the inner wall surface 21 of the housing portion 20.

On the other hand, the ceramic substrate according to the present example embodiment of the present invention is not limited to having the above-described structure provided that the first hollow is provided between at least a portion of the outer surface of the heat dissipation portion and the inner wall surface of the housing portion 20 in the extension direction of the heat dissipation portion.

Such another structure will be described with reference to the drawings.

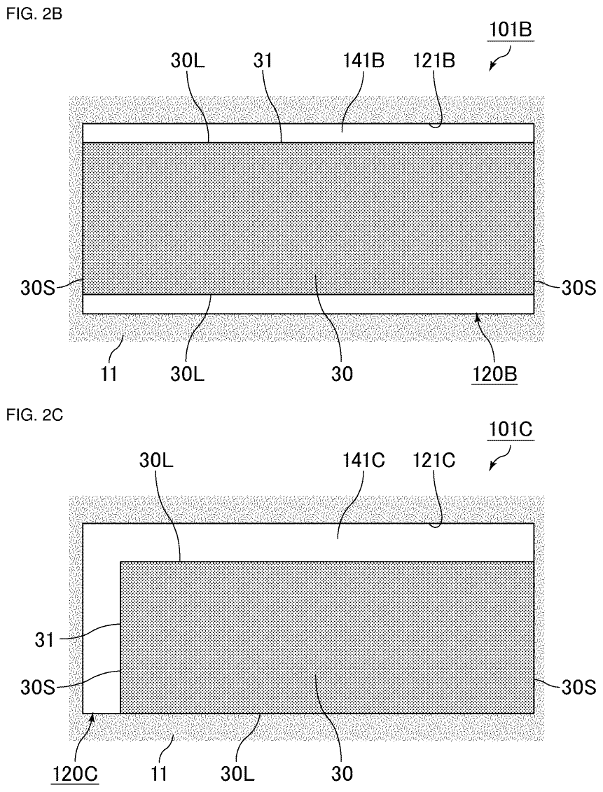

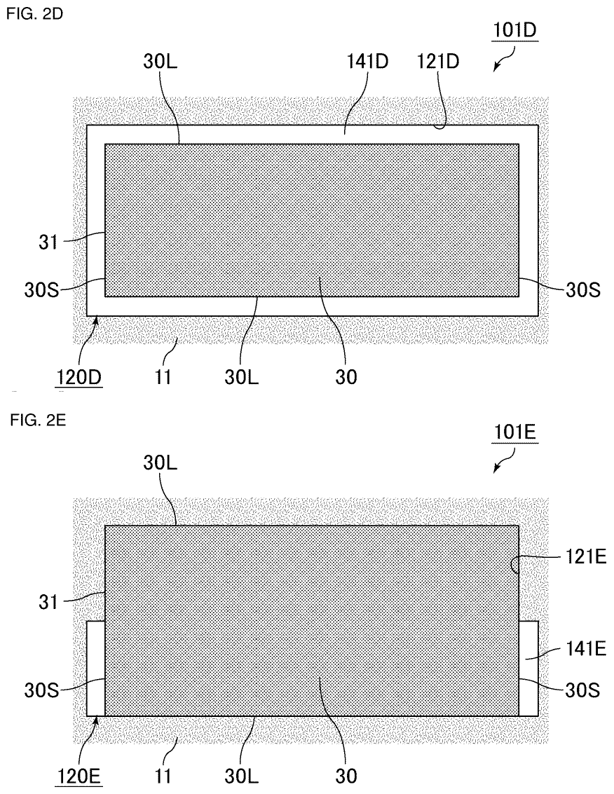

Each of FIGS. 2A to 2E is an enlarged schematic sectional view illustrating an example of the section of another ceramic substrate according to the present example embodiment of the present invention when cut passing a heat dissipation portion in the extension direction of the heat dissipation portion.

The ceramic substrate illustrated in each of FIGS. 2A to 2E has a structure the same as or similar to that of the above-described ceramic substrate 1, except that the shape of the housing portion housing the heat dissipation portion 30 and/or the heat dissipation portion is changed.

In a ceramic substrate 101A illustrated in FIG. 2A, the outline of a housing portion 120A is rectangular or substantially rectangular in plan view. In the ceramic substrate 101A, a first hollow 141A is provided between the outer surface 31 located on one short side portion 30S of the heat dissipation portion 30 and an inner wall surface 121A of the housing portion 120A, and the outer surface 31 located on the other short side portion 30S of the heat dissipation portion 30 is in contact with the inner wall surface 121A of the housing portion 120A. In this regard, the outer surface 31 located on both long side portions 30L of the heat dissipation portion 30 are in contact with the inner wall surface 121A of the housing portion 120A.

In a ceramic substrate 101B illustrated in FIG. 2B, the outline of a housing portion 120B is rectangular or substantially rectangular in plan view. In the ceramic substrate 101B, the outer surface 31 located on both short side portions 30S of the heat dissipation portion 30 is in contact with an inner wall surface 121B of the housing portion 120B. In this regard, a first hollow 141B is provided between the outer surface 31 located on both long side portions 30L of the heat dissipation portion 30 and the inner wall surface 121B of the housing portion 120B.

In a ceramic substrate 101C illustrated in FIG. 2C, the outline of a housing portion 120C is rectangular or substantially rectangular in plan view. In the ceramic substrate 101C, a first hollow 141C is provided between the outer surface 31 located on one short side portion 30S of the heat dissipation portion 30 and an inner wall surface 121C of the housing portion 120C, and the outer surface 31 located on the other short side portion 30S of the heat dissipation portion 30 is in contact with the inner wall surface 121C of the housing portion 120C. In this regard, the first hollow 141C is provided between the outer surface 31 located on one long side portion 30L of the heat dissipation portion 30 and the inner wall surface 121C of the housing portion 120C, and the outer surface 31 located on the other long side portion 30L of the heat dissipation portion 30 is in contact with the inner wall surface 121C of the housing portion 120C.

In a ceramic substrate 101D illustrated in FIG. 2D, the outline of a housing portion 120D is rectangular or substantially rectangular in plan view. In the ceramic substrate 101D, a first hollow 141D is provided between the outer surface 31 located on both short side portions 30S of the heat dissipation portion 30 and an inner wall surface 121D of the housing portion 120D. In addition, the first hollow 141D is provided between the outer surface 31 located on both long side portions 30L of the heat dissipation portion 30 and the inner wall surface 121D of the housing portion 120D.

That is, in the ceramic substrate 101D, the first hollow 141D is provided between the whole circumference of the outer surface 31 of the heat dissipation portion 30 and the inner wall surface 121D of the housing portion 120.

In a ceramic substrate 101E illustrated in FIG. 2E, the outline of a housing portion 120E: in plan view includes a protruding shape resulting from a combination of two rectangles having different sizes.

In the ceramic substrate 101E, a first hollow 141E is provided between a portion of the outer surface 31 located on both short side portions 30S of the heat dissipation portion 30 and the inner wall surface 121E of the housing portion 120E, and other portion of the outer surface 31 of the heat dissipation portion 30 (that is, a portion of both short side portions 30S and the entirety of both long side portions 30L) are in contact with the inner wall surface 121E of the housing portion 120E.

Accordingly, in the ceramic substrate according to the present example embodiment of the present invention, the other portion of the outer surface of the heat dissipation portion may be in contact with the inner wall surface of the housing portion provided that the first hollow is present between at least a portion of the outer surface of the heat dissipation portion and the inner wall surface of the housing portion in the extension direction of the heat dissipation portion. In addition, the first hollow may be present between the entire outer surface of the heat dissipation portion and the inner wall surface of the housing portion.

Regarding the ceramic substrates illustrated in FIG. 1C and FIGS. 2A to 2E, it is preferable that the first hollow is provided so as to expose a portion that is about an eighth or more of the entire circumference of the outer surface 31 of the heat dissipation portion 30.

The first hollow being provided in such a range enables the heat dissipation portion 30 to be sufficiently thermally exposed even when the ceramic substrate undergoes a thermal shock. Consequently, a defect can be reduced or prevented in the heat dissipation portion 30 and the ceramic layer 11, and a defect can be reduced or prevented in the vicinity of the interface between the heat dissipation portion 30 and the ceramic layer 11.

In addition, the ratio of the volume of the heat dissipation portion 30 to the capacity of the housing portion 20 is, for example, preferably [volume of heat dissipation portion]/[capacity of housing portion]×100(%)=about 90% or more and about 99.998% or less.

When such a ratio is provided, thermal expansion of the heat dissipation portion 30 is not readily hindered.

Therefore, thermal stress generated in the interior of the heat dissipation portion 30 can be reduced.

In the ceramic substrate 1 illustrated in FIG. 1B, the length L of the first hollow 41 is the same or substantially the same dimension as the thickness T of the heat dissipation portion 30 in the stacking direction V.

However, regarding the ceramic substrate according to the present example embodiment of the present invention, when the extension direction of the heat dissipation portion is in the direction perpendicular or substantially perpendicular to the stacking direction of the multilayer body, the length of the first hollow may be smaller than or larger than the thickness of the heat dissipation portion in the stacking direction of the multilayer body.

Such an aspect will be described with reference to the drawings.

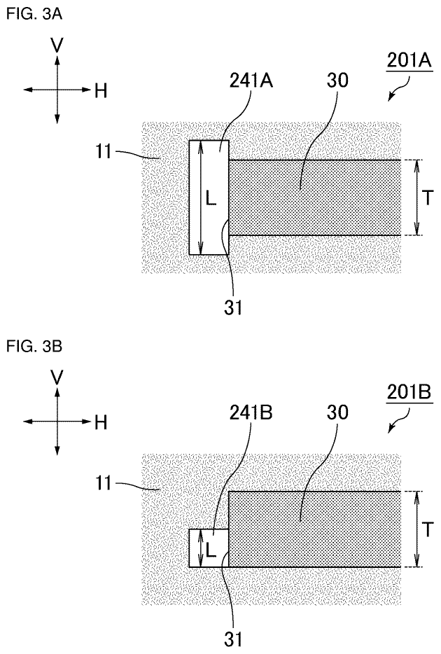

Each of FIG. 3A and FIG. 3B is a schematic sectional view illustrating an example of the vicinity of the heat dissipation portion in another ceramic substrate according to an example embodiment of the present invention.

The ceramic substrate illustrated in each of FIG. 3A and FIG. 3B has a structure the same as or similar to that of the above-described ceramic substrate 1 except that the length of the housing portion to house the heat dissipation portion 30 in the stacking direction V is changed.

In the ceramic substrate 201A illustrated in FIG. 3A, the length L of the first hollow 241A is larger than the thickness T of the heat dissipation portion 30 in the stacking direction V.

In this regard, in the ceramic substrate 201B illustrated in FIG. 3B, the length L of the first hollow 241B is smaller than the thickness T of the heat dissipation portion 30 in the stacking direction V.

Each of the various configurations of ceramic substrates according to example embodiments of the present invention will be described below in detail.

### Ceramic Layer

In ceramic substrates according to example embodiments of the present invention, the ceramic layer may be a sintered body of a ceramic green sheet. The ceramic green sheet can be molded by, for example, applying a doctor blade method or the like to a ceramic slurry on a carrier film.

The ceramic slurry may include, for example, a ceramic powder, a binder, and a plasticizer. For example, a low temperature co-sintered ceramics (LTCC) material can be used as a ceramic material. The low-temperature-sinterable ceramic material is a ceramic material that can be sintered at a temperature of, for example, about 1,000° C. or lower and that can be co-fired with Au, Ag, Cu, or the like having low resistivity. Specific examples of the low-temperature-sinterable ceramic material include glass-composite-based low-temperature-sinterable ceramic materials in which borosilicate glass is mixed in a ceramic powder, such as alumina, zirconia, magnesia, and forsterite, crystallized-glass-based low-temperature-sinterable ceramic materials by using ZnO—MgO—Al₂O₃—SiO₂-based crystallized glass, and non-glass-based low-temperature-sinterable ceramic materials by using BaO—Al₂O₃—SiO₂-based ceramic powders, Al₂O₃—CaO—SiO₂—B₂O₃-based ceramic powders, Al₂O₃—CaO—SiO₂—MgO—B₂O₃-based ceramic powders, and the like.

There is no particular limitation regarding the thickness of the ceramic layer, and the thickness is, for example, preferably about 5 μm or more and about 200 μm or less.

It is preferable that the thickness of the ceramic layer is appropriately designed in accordance with the number of stacked ceramic layers, the thickness of the whole ceramic substrate, and the like.

### Heat Dissipation Portion

In a ceramic substrate according to an example embodiment of the present invention, the thermal conductivity of the heat dissipation portion is, for example, preferably about 100 W/m·K or more and about 2,000 W/m·K or less.

The thermal conductivity of the heat dissipation portion being within the above-described range enables the heat from the heat generation component 71 to be favorably emitted to the outside.

In a ceramic substrate according to an example embodiment of the present invention, the coefficient of linear expansion of the heat dissipation portion is, for example, preferably about 0.9×10⁻⁶/K(m) or more and about 35×10⁻⁶/K(m) or less.

Even when the coefficient of linear expansion of the heat dissipation portion is within the above-described range, since the first hollow is provided in the ceramic substrate according to the present example embodiment of the present invention so that the heat dissipation portion can thermally expand, thermal stress is not readily generated in the heat dissipation portion.

In this regard, in the ceramic substrate according to the present example embodiment of the present invention, the coefficient of linear expansion of the heat dissipation portion in the extension direction of the heat dissipation portion may differ from the coefficient of linear expansion in the direction perpendicular to the extension direction of the heat dissipation portion.

Examples of such a heat dissipation portion include heat dissipation portions made of a graphite sheet.

When the heat dissipation portion is made of a graphite sheet, the coefficient of linear expansion thereof is, for example, preferably about −1×10⁻⁶/K (m) or more and about 5×10^{31 6}/K (m) or less. In addition, the coefficient of linear expansion in the direction perpendicular or substantially perpendicular to the extension direction of the heat dissipation portion is, for example, preferably about 6×10⁻⁶/K (m) or more and about 40×10⁻⁶/K (m) or less.

Regarding the heat dissipation portion, for example, a heat dissipation sheet or a heat dissipation column can be used.

Regarding the heat dissipation sheet, for example, a metal plate, metal foil, a graphite sheet, and a copper-coated graphite sheet are preferable.

Of these, for example, a graphite sheet and a copper-coated graphite sheet are more preferable.

The graphite sheet or the copper-coated graphite sheet has a high thermal conductivity in the direction along the plane of the sheet, and the heat transferred to the graphite sheet or the copper-coated graphite sheet is promptly diffused in the direction along the plane of the sheet. Consequently, the graphite sheet and the copper-coated graphite sheet are suitable for the heat dissipation portion of a ceramic substrate according to an example embodiment of the present invention.

Regarding the type of the metal when the metal plate or metal foil is used as the heat dissipation portion, for example, copper, silver, tungsten, molybdenum, aluminum, alloys including these metals, or the like can be used.

### First Heat Dissipation Via and Second Heat Dissipation Via

In a ceramic substrate according to an example embodiment of the present invention, for example, it is preferable that the first heat dissipation via and the second heat dissipation via be made of a member having a thermal conductivity of about 30 W/m·K or more and about 2,000 W/m·K or less.

The first heat dissipation via and the second heat dissipation via having such a thermal conductivity enable the heat from the heat generation component to be favorably emitted to the outside.

Regarding the first heat dissipation via and the second heat dissipation via, a solidified material of, for example, a thermally conductive paste, a metal column, a column made of a carbon material, or the like can be used.

The thermally conductive paste may include, for example, a thermally conductive particle and a resin.

Examples of the thermally conductive particle include a metal particles formed of copper, silver, tungsten, molybdenum, aluminum, or an alloy including these metals and carbon-based particles, such as graphite, graphene, and a carbon nanotube. In this regard, the thermally conductive paste may include mixtures of the above-described metal particles and the above-described carbon-based particles.

The metal column may be made of, for example, copper, silver, tungsten, molybdenum, aluminum, or an alloy including these metals.

The column defined by a carbon material may be made of, for example, a carbon-based material, such as graphite, graphene, or a carbon nanotube.

In this regard, the first heat dissipation via and the second heat dissipation via may be made of the same material or may be made of different materials.

### Heat Dissipation Pad

In a ceramic substrate according to an example embodiment of the present invention, it is preferable that the heat dissipation pad has a thermal conductivity of, for example, about 100 W/m·K or more and about 2,000 W/m·K or less.

When the heat dissipation pad has such a thermal conductivity, the heat from the heat generation component is readily transferred to first heat dissipation via.

Regarding the heat dissipation pad, for example, a solidified material of a thermally conductive paste, a metal pad, a pad made of a carbon material, or the like can be used.

The thermally conductive paste may include, for example, a thermally conductive particle and a resin.

Examples of the thermally conductive particle include a metal particles including copper, silver, tungsten, molybdenum, aluminum, or an alloy including these metals and carbon-based particles, such as graphite, graphene, and a carbon nanotube. In this regard, the thermally conductive paste may include mixtures of the above-described metal particles and the above-described carbon-based particles.

The metal pad may be made of, for example, copper, silver, tungsten, molybdenum, aluminum, or an alloy including these metals.

The pad defined by a carbon material may be made of, for example, a carbon-based material, such as graphite, graphene, or a carbon nanotube.

### Outer Heat Dissipation Portion

In a ceramic substrate according to an example embodiment of the present invention, there is no particular limitation regarding the outer heat dissipation portion, and a heat sink, a radiation fin, a vapor chamber, or the like can be used.

### Surface Electrode, Inner Conductor, and Wiring Via

A surface electrode, an inner conductor, and a wiring via may be formed by an electrically conductive paste being fired.

There is no particular limitation regarding the electrically conductive paste. For example, an electrically conductive metal material, a binder, and a plasticizer may be included. A common base material for adjusting shrinkage (ceramic powder) may be added to the electrically conductive paste. Regarding the electrically conductive metal material included in the electrically conductive paste, for example, a metal including at least one of Ag, a Ag—Pt alloy, a Ag—Pd alloy, Cu, Ni, Pt, Pd, W, Mo, or Au as a primary component can be used. Of these electrically conductive metal materials, for example, Ag, a Ag—Pt alloy, a Ag—Pd alloy, and Cu have a low resistivity and, therefore, can be more preferably used for, in particular, a conductor pattern for high frequency.

The electrically conductive paste may include a glass component but is not limited to including a glass component.

The electrically conductive paste including a glass component enables the sinterability between an electronic component main body and the surface electrode, the inner conductor, and the wiring via to be improved.

On the other hand, when the electrically conductive paste does not include a glass component, the purity of a metal included in the electrically conductive paste increases, and the purity of the metal included in the surface electrode, inner conductor, and wiring via also increases. Consequently, the resistivity values of the surface electrode, the inner conductor, and the wiring via can be decreased.

The proportion of the glass component included in the electrically conductive paste being adjusted enables the surface electrode, the inner conductor, and the wiring via having predetermined electrical characteristics and structures to be obtained.

### Heat Generation Component and Passive Component

The heat generation component is an electrical component that generates heat by itself during operation, and examples include known components, such as processors, LEDs, power amplifiers, and camera modules.

Examples of the passive component include known components, such as capacitors and inductors.

Next, an example of a method for manufacturing a ceramic substrate according to an example embodiment of the present invention will be described.

A method for manufacturing a ceramic substrate according to an example embodiment of the present invention includes (1) an unfired multilayer body preparing step, (2) a firing step, and (3) a constraining layer removal step.

In this regard, (1) unfired multilayer body preparing step includes <Ceramic green sheet preparation sub-step>, <Hole portion·via hole formation sub-step>, <Electrically conductive paste arrangement sub-step>, <Constraining layer preparation sub-step>, and <Ceramic green sheet stacking sub-step>.

Each step will be described in detail with reference to the drawings.

### (1) Unfired Multilayer Body Preparing Step

### Ceramic Green Sheet Preparation Sub-Step

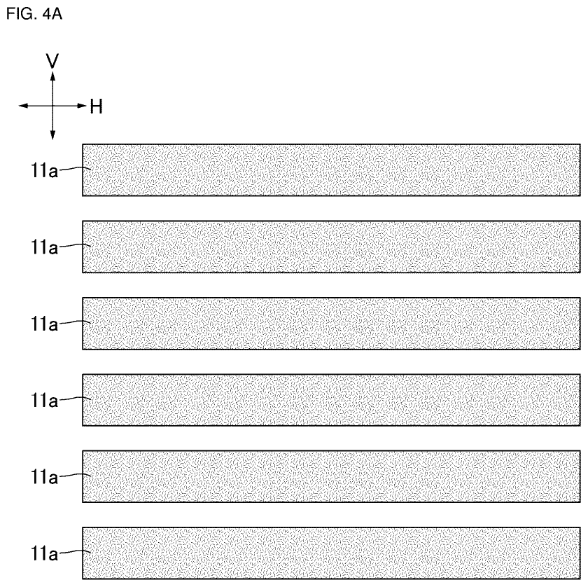

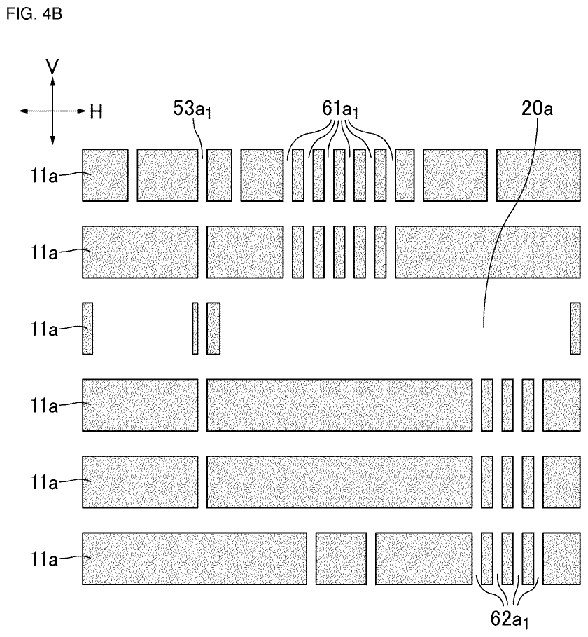

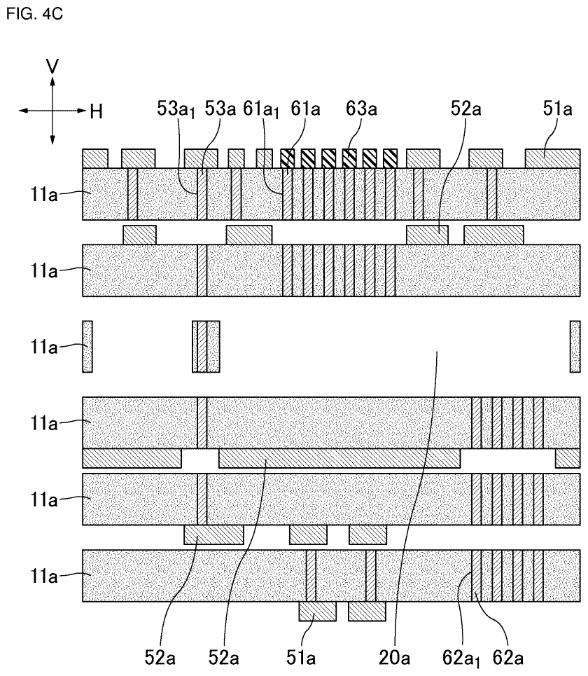

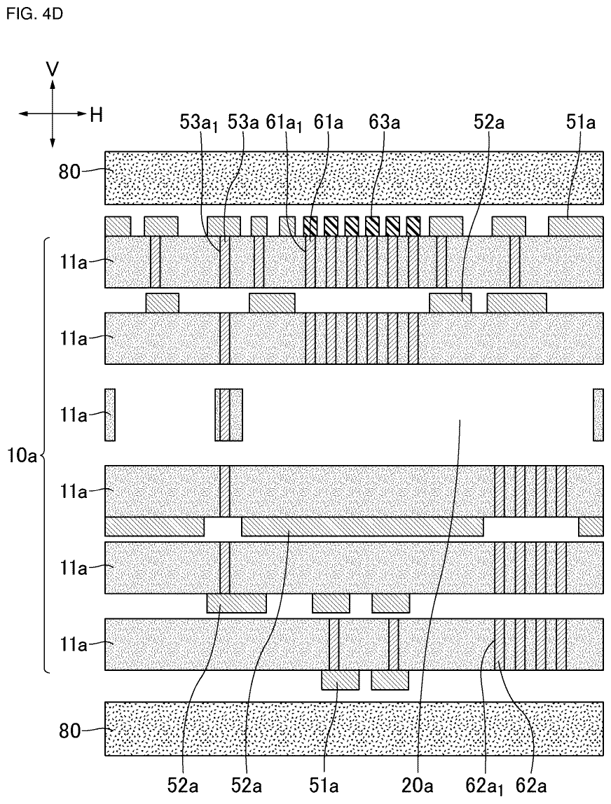

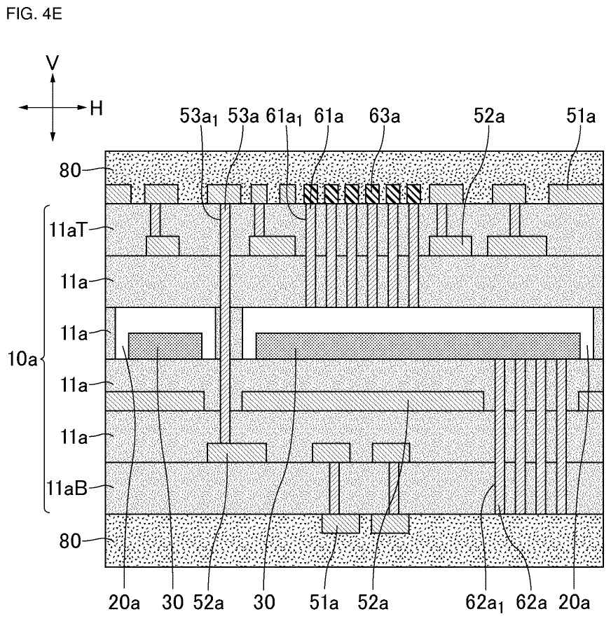

FIG. 4A is a schematic sectional view illustrating an example of the ceramic green sheet preparation sub-step in the method for manufacturing a ceramic substrate according to the present example embodiment of the present invention.

In the ceramic green sheet preparation sub-step, a slurry is produced by mixing an optional amount of, for example, LTCC material, binder, and plasticizer.

Subsequently, the slurry is applied to carrier films (not illustrated in the drawings) so as to form a plurality of ceramic green sheets 11a, as illustrated in FIG. 4A. Regarding application of the slurry, for example, a lip coater or a doctor blade can be used.

In this regard, the ceramic green sheet 11a shrinks by being fired through the firing step described later. It is preferable that the size of the ceramic green sheet 11a is appropriately determined in consideration of shrinkage due to firing.

### Hole Portion·Via Hole Formation Sub-Step

FIG. 4B is a schematic sectional view illustrating an example of the hole portion·via hole formation sub-step in the method for manufacturing a ceramic substrate according to the present example embodiment of the present invention.

Subsequently, as illustrated in FIG. 4B, a hole portion 20a to house a heat dissipation portion, a via hole 53a₁ for the wiring via, a via hole 61a₁ for a first heat dissipation via, and a via hole 62a₁ for a second heat dissipation via are formed at predetermined positions of the ceramic green sheet 11a.

There is no particular limitation regarding the method for forming the hole portion 20a and each via hole, and formation may be performed by, for example, laser beam machining, cutter machining, drill machining, or the like.

### Electrically Conductive Paste Arrangement Sub-Step

FIG. 4C is a schematic sectional view illustrating an example of the electrically conductive paste arrangement sub-step in the method for manufacturing a ceramic substrate according to the present example embodiment of the present invention.

Subsequently, as illustrated in FIG. 4C, an electrically conductive paste 53a for a wiring via, a thermally conductive paste 61a for the first heat dissipation via, and a thermally conductive paste 62a for the second heat dissipation via are arranged in the via hole 53a₁ for the wiring via, the via hole 61a₁ for the first heat dissipation via, and the via hole 62a₁ for the second heat dissipation via, respectively.

Thereafter, an electrically conductive paste 52a for an inner conductor is formed at a predetermined position of the ceramic green sheet 11a defining the interior of the produced ceramic substrate. The electrically conductive paste 52a for an inner conductor is formed of a material defining an inner conductor 52 by being fired in the firing step.

In addition, an electrically conductive paste 51a for a surface electrode and a thermally conductive paste 63a for a heat dissipation pad are arranged at predetermined positions of the ceramic green sheet 11a defining the surface of the produced ceramic substrate, that is, at predetermined portions of an outer layer.

The electrically conductive paste 51a for a surface electrode and the thermally conductive paste 63a for a heat dissipation pad are formed of a material defining a surface electrode 51 and a heat dissipation pad 63 by being fired in the firing step.

In this regard, in general, the electrically conductive paste 53a for a wiring via, the electrically conductive paste 51a for a surface electrode, and the thermally conductive paste 63a for a heat dissipation pad are arranged while a principal surface of the ceramic green sheet 11a not provided with the carrier film faces upward.

In the produced ceramic substrate, when the surface electrode and the heat dissipation pad are arranged on the bottom surface, the ceramic green sheet defining the bottom surface may be stacked upside down in a ceramic green sheet stacking sub-step described later.

In FIG. 4C, for convenience of the steps described later, three ceramic green sheets 11a located in a lower section are illustrated upside down.

In this regard, in the ceramic green sheet stacking sub-step described later, the ceramic green sheets provided with the electrically conductive paste for a wiring via, the electrically conductive paste for a surface electrode, and the thermally conductive paste for a heat dissipation pad may be stacked while the directions of the principal surfaces are the same or substantially the same. The electrically conductive paste for a surface electrode and the thermally conductive paste for a heat dissipation pad are not arranged on the bottom surface of the ceramic green sheet stacked as the lowermost layer. In such an instance, the electrically conductive paste for a surface electrode and the thermally conductive paste for a heat dissipation pad may be separately arranged on the bottom surface of the ceramic green sheet stacked as the lowermost layer after the stacking. Alternatively, after stacking, a transfer sheet printed with the surface electrode (electrically conductive paste for a surface electrode) and the heat dissipation pad (thermally conductive paste for a heat dissipation pad) may be arranged on the bottom surface of the ceramic green sheet stacked as the lowermost layer, and transfer may be performed.

### Constraining Layer Preparation Sub-Step

FIG. 4D is a schematic sectional view illustrating an example of the constraining layer preparation sub-step in the method for manufacturing a ceramic substrate according to the present example embodiment of the present invention.

Subsequently, a constraining layer 80 is prepared as illustrated in FIG. 4D.

The constraining layer 80 is a layer including an inorganic material that is substantially not sintered at a firing temperature, and it is preferable that the constraining layer 80 is made of, for example, 100% by weight (impurities are allowed) of Al₂O₃.

The constraining layer 80 including Al₂O₃ is a sheet that is substantially not sintered at the sintering temperature of the ceramic green sheet 11a.

The constraining layer 80 is substantially not sintered during firing so that shrinkage does not occur and acts on an unfired multilayer body 10a to reduce or prevent shrinkage from occurring in the principal surface direction. As a result, dimensional precision of various members after firing can be improved.

### Ceramic Green Sheet Stacking Sub-Step

FIG. 4E is a schematic sectional view illustrating an example of the ceramic green sheet stacking sub-step in the method for manufacturing a ceramic substrate according to the present example embodiment of the present invention.

Subsequently, as illustrated in FIG. 4E, the ceramic green sheet 11a is peeled off the carrier film (not illustrated in the drawing) and stacked.

In such an instance, a heat dissipation portion 30 is arranged in the hole portion 20a.

In addition, the constraining layer 80 is stacked on an outer side portion of the uppermost ceramic green sheet (for convenience, a ceramic green sheet indicated by reference “11aT”) and the lowermost ceramic green sheet (for convenience, a ceramic green sheet indicated by reference “11aB”).

### (2) Firing Step

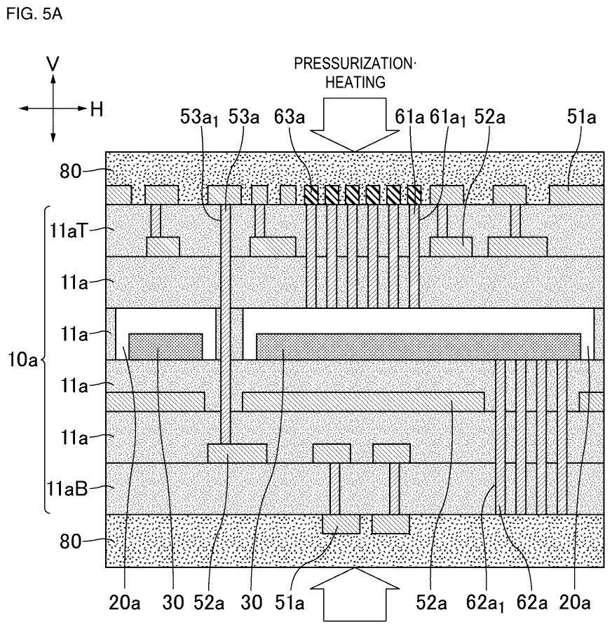

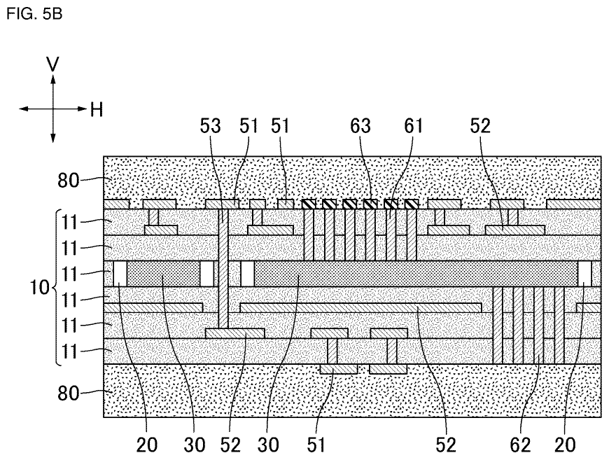

FIG. 5A is a schematic sectional view illustrating an example of a firing step in the method for manufacturing a ceramic substrate according to the an example embodiment of the present invention.

FIG. 5B is a schematic sectional view illustrating an example of the ceramic substrate provided with the constraining layer after the firing step in the method for manufacturing a ceramic substrate according to the present example embodiment of the present invention.

Subsequently, as illustrated in FIG. 5A, the unfired multilayer body 10a is fired by performing heating while pressurization is performed.

There is no particular limitation regarding the firing temperature provided that the constraining layer 80 is not sintered at the firing temperature, and, for example, about 1,000° C. or lower is preferable.

In this regard, pressurization is not indispensable in the firing step of the method for manufacturing a ceramic substrate according to the present example embodiment of the present invention.

Firing being performed under such conditions enables the ceramic substrate in which the ceramic green sheet 11a defines as the ceramic layer, the hole portion 20a defines as the housing portion, and the heat dissipation portion is arranged in the housing portion to be produced.

In this regard, in the firing step, firing is performed so that the housing portion of the ceramic substrate formed through the firing step has a size in which the first hollow is formed between at least a portion of the outer surface of the heat dissipation portion and the inner wall surface of the housing portion in the extension direction of the heat dissipation portion of the ceramic substrate produced through the firing step.

The electrically conductive paste 51a for a surface electrode, the electrically conductive paste 52a for an inner conductor, and the electrically conductive paste 53a for a wiring via are converted to the surface electrode, the inner conductor, and the conductor via, respectively, by firing.

In addition, the thermally conductive paste 61a for the first heat dissipation via and the thermally conductive paste 62a for the second heat dissipation via are converted to the first heat dissipation via and the second heat dissipation via, respectively, by firing.

The ceramic substrate 1 in which the ceramic layer 11 is disposed, as illustrated in FIG. 5B, can be produced through the firing step.

### (3) Constraining Layer Removal Step

After the above-described firing is performed, the constraining layer 80 is removed by a treatment, such as sandblast, for example.

The ceramic substrates according to example embodiments of the present invention can be produced through the above-described steps.

Thereafter, the outer heat dissipation portion, the heat generation component, and the passive component are arranged at predetermined positions of the ceramic substrate so that the ceramic substrate illustrated in FIG. 1 is formed.

### OTHER EXAMPLE EMBODIMENTS

In the above-described ceramic substrates according to example embodiments of the present invention, the extension direction of the heat dissipation portion is the direction perpendicular or substantially perpendicular to the stacking direction of the multilayer body. However, in ceramic substrates according to example embodiments of the present invention, the extension direction of the heat dissipation portion may be oblique to the stacking direction.

In the above-described ceramic substrate according to the present example embodiment of the present invention, the end portion of the heat dissipation portion in the extension direction has a shape perpendicular or substantially perpendicular to the extension direction of the heat dissipation portion. In addition, in the above-described ceramic substrate according to the present example embodiment of the present invention, the inner wall surface of the housing portion in the extension direction of the heat dissipation portion has a shape perpendicular or substantially perpendicular to the extension direction of the heat dissipation portion.

However, in a ceramic substrate according to an example embodiment of the present invention, there is no particular limitation regarding the shape of the above-described end portion and the shape of the inner wall surface of the housing portion provided that the first hollow is present between at least a portion of the outer surface of the heat dissipation portion and the inner wall surface of the housing portion in the extension direction of the heat dissipation portion. The shape may be, for example, a shape oblique to the extension direction of the heat dissipation portion or a shape of a curved surface, or a recessed portion, a protruding portion, or the like may be disposed.

In the above-described ceramic substrate according to the present example embodiment of the present invention, the outer surface of the heat dissipation portion is in contact with the inner wall surface of the housing portion in the direction perpendicular or substantially perpendicular to the extension direction of the heat dissipation portion.

However, in a ceramic substrate according to an example embodiments the present invention, a second hollow may be provided between at least a portion of the outer surface of the heat dissipation portion and the inner wall surface of the housing portion in the direction perpendicular or substantially perpendicular to the extension direction of the heat dissipation portion.

When the second hollow is provided, the heat dissipation portion can thermally toward expand the second hollow. Consequently, the thermal stress generated in the heat dissipation portion and the thermal stress generated at the interface between the heat dissipation portion and the ceramic layer can be reduced.

In the above-described ceramic substrate according to the present example embodiment of the present invention, the first heat dissipation via and the second heat dissipation via are in contact with the ceramic layer.

However, in a ceramic substrate according to an example embodiment of the present invention, a hollow may be provided between the first heat dissipation via and the ceramic layer and between the second heat dissipation via and the ceramic layer.

The first heat dissipation via and the second heat dissipation via also thermally expand by undergoing heat. Therefore, thermal stress is also generated in the first heat dissipation via and the second heat dissipation via. Such thermal stress causes a defect, such as a crack, in the first heat dissipation via and the second heat dissipation via. The hollow being provided between the first heat dissipation via and the ceramic layer and between the second heat dissipation via and the ceramic layer enables the first heat dissipation via and the second heat dissipation via to thermally expand toward the hollow so that the above-described thermal stress can be reduced.

In a method for manufacturing a ceramic substrate according to the present example embodiment of the present invention, (1) a unfired multilayer body preparing step includes a ceramic green sheet preparation sub-step, a hole portion·via hole formation sub-step, an electrically conductive paste arrangement sub-step, a constraining layer preparation sub-step, and a ceramic green sheet stacking sub-step.

However, in (1) an unfired multilayer body preparing step of a method for manufacturing a ceramic substrate according to an example embodiment of the present invention, some sub-steps are not limited to being performed, and another sub-step may be added provided that the unfired multilayer body including the ceramic green sheet multilayer body that includes a plurality of stacked ceramic green sheets and that includes a hole portion in the interior and the heat dissipation portion arranged in the hole portion can be prepared. For example, the above-described method for manufacturing a ceramic substrate according to the present example embodiment of the present invention includes a step of performing a constraining layer preparation sub-step. However, in a method for manufacturing a ceramic substrate according to an example embodiment of the present invention, the constraining layer preparation sub-step may be skipped. In such an instance, the constraining layer is not stacked in a ceramic green sheet stacking sub-step, and (3) a constraining layer removal strep is not performed.

### EXAMPLES

Examples more specifically disclosing ceramic substrates according to example embodiments of the present invention will be described below. In this regard, the present invention is not limited to only these examples.

### Example 1

### (1) Unfired Multilayer Body Preparing Step

### Ceramic Green Sheet Preparation Sub-Step

A ceramic slurry was produced by mixing an alumina powder and a glass powder at a ratio of about 40:60 on a weight ratio basis, adding each of a binder, a dispersing agent, a plasticizer, an organic solvent, and the like in an appropriate amount to the resulting powder mixture, and performing mixing.

In this regard, a borosilicate glass powder having a composition including SiO₂: about 59% by weight, B₂O₃: about 10% by weight, CaO: about 25% by weight, and Al₂O₃: about 6% by weight was used as the glass powder.

Subsequently, the above-described ceramic slurry was defoamed. Thereafter, 15 ceramic green sheets having a thickness of, for example, about 80 μm were produced on a carrier film by using a doctor blade.

### Hole Portion·Via Hole Formation Sub-Step

Laser machining was performed so that a hole portion passing through a ceramic green sheet in the thickness direction was formed in one of the prepared ceramic green sheets. In this regard, in such an instance, for example, the shape of the hole portion was set to be a rectangle or substantially rectangular of length×width=about 2.0 mm×about 2.0 mm in plan view.

### Ceramic Green Sheet Stacking Sub-Step

A graphite sheet (heat dissipation portion) of, for example, length×width×thickness=about 1.80 mm×about 1.80 mm×about 40 μm was prepared.

Subsequently, two alumina sheets defining and functioning as constraining layers were prepared, and 7 ceramic green sheets were provided on each constraining layer, the ceramic green sheets including no hole portion.

Next, a ceramic green sheet including a hole portion was stacked on one ceramic green sheet multilayer body, and a graphite sheet was arranged in the hole portion.

Thereafter, the other ceramic green sheet multilayer body was arranged on the ceramic green sheet including the hole portion so that the constraining layer was located as the outermost layer.

The unfired multilayer body including a ceramic green sheet multilayer body that had the hole portion in the interior and the heat dissipation portion arranged in the hole portion was prepared through the above-described steps.

### (2) Firing Step

Thereafter, the unfired multilayer body was fired at 1, 000° C. or lower so as to be converted to a ceramic substrate including the constraining layer as the outermost layer.

In the firing step, the ceramic green sheet having a thickness of, for example, about 80 μm was fired so as to be converted to a ceramic layer having a thickness of about 40 μm. In addition, the hole portion was converted to a housing portion.

Subsequently, the constraining layer was removed by performing, for example, ultrasonic cleaning and wet blast.

The ceramic substrate according to Example 1 was produced through the above-described steps.

### Example 2

A ceramic substrate according to Example 2 was produced in a manner the same as or similar to that in Example 1 except that the dimension of the graphite sheet was changed to, for example, length×width=about 1.96 mm×about 1.96 mm in plan view.

### Example 3

A ceramic substrate according to Example 3 was produced in a manner the same as or similar to that in Example 1 except that the dimension of the graphite sheet was changed to length x width=about 1.98 mm×about 1.98 mm in plan view.

### Example 4

A ceramic substrate according to Example 4 was produced in a manner the same as or similar to that in Example 3 except that the graphite sheet was changed to a copper-coated graphite sheet.

### Comparative Example 1

A ceramic substrate according to Comparative example 1 was produced in a manner similar to that in Example 1 except that the dimension of the graphite sheet was changed to length×width=about 2.00 mm×about 2.00 mm in plan view.

### Comparative Example 2

A ceramic substrate according to Comparative example 2 was produced in a manner similar to that in Example 1 except that the dimension of the graphite sheet was changed to length×width=about 2.02 mm×about 2.02 mm in plan view and that the graphite sheet was arranged as described below.

In Comparative example 2, the dimension of the graphite sheet in plan view was larger than the dimension of the hole portion in plan view. Consequently, when the graphite sheet was arranged in the hole portion, the graphite sheet was not fit in the hole portion. Therefore, in Comparative example 2, the graphite sheet was arranged so as to take on a state in which a portion of the graphite sheet was in the hole portion and the other portion was floated. Thereafter, other ceramic green sheets were stacked.

### Comparative Example 3

A ceramic substrate according to Comparative example 3 was produced in a manner similar to that in Example 1 except that a hole portion was not formed in the ceramic green sheet, that a graphite sheet was not provided, and that 15 ceramic green sheets having no hole portion were stacked.

### Comparative Example 4

A ceramic substrate according to Comparative example 4 was produced in a manner similar to that in Comparative example 1 except that the graphite sheet was changed to a copper-coated graphite sheet.

TABLE 1

| | Heat dissipation portion | | | |
|---|---|---|---|---|
| | | Dimension in plan | | Flexural |
| | | view (length mm × | First | strength |
| | Type | width mm) | hollow | (MPa) |
| Example 1 | graphite | 1.80 × 1.80 | present | 300 |
| | sheet | | | |
| Example 2 | graphite | 1.96 × 1.96 | present | 300 |
| | sheet | | | |
| Example 3 | graphite | 1.98 × 1.98 | present | 300 |
| | sheet | | | |
| Example 4 | copper- | 1.98 × 1.98 | present | 320 |
| | coated | | | |
| | graphite | | | |
| | sheet | | | |
| Comparative | graphite | 2.00 × 2.00 | none | 250 |
| example 1 | sheet | | | |
| Comparative | graphite | 2.02 × 2.02 | none | 150 |
| example 2 | sheet | | | |
| Comparative | — | — | — | 280 |
| example 3 | | | | |
| Comparative | copper- | 2.00 × 2.00 | none | 300 |
| example 4 | coated | | | |
| | graphite | | | |
| | sheet | | | |

### Identification of First Hollow

The ceramic substrate according to each of Examples 1 to 4 and Comparative examples 1, 2, and 4 was vertically cut in the extension direction of the graphite sheet, and whether the first hollow was present between the outer surface of the graphite sheet and the inner wall surface of the housing portion in the extension direction of the graphite sheet was observed.

As a result, it was ascertained that the first hollow was present in the ceramic substrates according to Examples 1 to 4 and that the outer surface of the graphite sheet was in contact with the inner wall surface of the housing portion and the first hollow was not present in the ceramic substrates according to Comparative examples 1, 2, and 4.

### Flexural Strength Test

Regarding the ceramic substrate according to each of the Examples and each of the Comparative examples, the flexural strength was evaluated by a three-point bending test. A support table was made of stainless steel, and the distance between support points was set to be, for example, about 25 mm. A push rod was, made of stainless steel, and the tip was set to have the shape of a hemisphere of, for example, R=about 2.5 mm. The sample was placed on the central portion of the support table, and the push rod was made to come into contact with the central portion of the upper surface of the sample. A downward external force was applied to the push rod, and pushing down was performed until the sample was fractured. The results are presented in Table 1.

As presented in Table 1, the ceramic substrates according to Examples 1 to 3 had higher flexural strength than the ceramic substrates according to Comparative examples 1 to 3.

The reason for this is considered to be that since the first hollow was provided in the ceramic substrates according to Examples 1 to 3, the heat stress generated in the graphite sheet and the graphite layer due to the heat during the firing could be relaxed, and a crack did not occur in the graphite sheet and the ceramic layer.

In this regard, the flexural strength of the ceramic substrate according to Comparative example 4 was the same or substantially the same level as the flexural strength of the ceramic substrates according to Examples 1 to 3. The reason for this is considered to be that the strength of the copper-coated graphite sheet was higher than the strength of the graphite sheet.

When Example 4 and Comparative example 4 in which the copper-coated graphite was used as the heat dissipation portion are compared, it can be ascertained that the ceramic substrate according to Example 4 has higher flexural strength than the ceramic substrate according to Comparative example 4. Consequently, it can be assumed that the ceramic substrate according to Comparative example 4 had lower flexural strength than the ceramic substrate according to Example 4 since cracks were formed in the copper-coated graphite and the ceramic layer.

### Heat Cycle Test

Regarding the ceramic substrates according to each of Example 3, Example 4, Comparative example 3, and Comparative example 4, 90 samples were prepared.

Each ceramic substrate was subjected to steps of heating to about 85° C., leaving to stand for about 0.5 hours, cooling to about −40° C., and leaving to stand for about 0.5 hours. A heat cycle was set to be the above-described heating and cooling, and the heat cycle was repeated about 1, 000 times.

The samples were subjected to heat cycles, 15 samples were taken at each stage of 0 times (initial stage), 100 times, 200 times, 500 times, 700 times, and 1,000 times, the flexural strength test was performed, and the heat cycle resistance was evaluated. The results are presented in Table 2.

The evaluation criteria are as described below.
∘: the number of samples the flexural strength of which about 30% or more decreased relative to the initial flexural strength was 0 out of 15
Δ: the number of samples the flexural strength of which about 30% or more decreased relative to the initial flexural strength was 1 out of 15
x: the number of samples the flexural strength of which about 30% or more decreased relative to the initial flexural strength was 2 or more out of 15

TABLE 2

| | Number of heat cycles | | | | | |
|---|---|---|---|---|---|---|
| | Initial flexural | 100 | 200 | 500 | 700 | 1,000 |
| | strength (MPa) | times | times | times | times | times |
| Example 3 | 300 | ∘ | ∘ | ∘ | ∘ | ∘ |
| Example 4 | 320 | ∘ | ∘ | ∘ | ∘ | ∘ |
| Comparative | 280 | ∘ | ∘ | ∘ | ∘ | ∘ |
| example 3 | | | | | | |
| Comparative | 300 | Δ | x | x | x | x |
| example 4 | | | | | | |

As presented in Table 2, it was discovered that the ceramic substrates according to Examples 3 and 4 had high heat cycle resistance.

In addition, as presented in Table 2, it was discovered that the ceramic substrate according to Comparative example 3 had high heat cycle resistance but, as presented in Table 1, had low initial flexural strength.

In addition, as presented in Table 2, it was discovered that the ceramic substrate according to Comparative example 4 had low heat cycle resistance. The reason for this is considered to be that, regarding the ceramic substrate according to Comparative example 4, since the copper-coated graphite sheet serving as the heat dissipation portion is just fit in the housing portion, the thermal stress generated in the copper-coated graphite sheet and the ceramic layer cannot be relaxed.

Accordingly, it was discovered that the ceramic substrate according to the present invention has high initial flexural strength and, in addition, high heat cycle resistance.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A ceramic substrate comprising:
a multilayer body including a plurality of stacked ceramic layers and a housing portion in an interior of the multilayer body; and
a heat dissipation portion in the housing portion; wherein
a first hollow is provided between at least a portion of an outer surface of the heat dissipation portion and an inner wall surface of the housing portion in an extension direction of the heat dissipation portion; and
the heat dissipation portion includes a graphite sheet.

2. The ceramic substrate according to claim 1, wherein the heat dissipation portion includes a copper-attached graphite sheet.

3. The ceramic substrate according to claim 1, wherein
at least a portion of the outer surface of the heat dissipation portion is in contact with the inner wall surface of the housing portion; and
no chemical bond due to mutual diffusion is present in a contact portion between the outer surface of the heat dissipation portion and the inner wall surface of the housing portion.

4. The ceramic substrate according to claim 1, wherein
the extension direction of the heat dissipation portion is a direction perpendicular or substantially perpendicular to a stacking direction of the multilayer body; and
a length of the first hollow in the stacking direction of the multilayer body is about one half or more of a thickness of the heat dissipation portion.

5. The ceramic substrate according to claim 1, further comprising:
a plurality of surface electrodes on surfaces of the multilayer body; and
a plurality of inner conductors in the interior of the multilayer body.

6. The ceramic substrate according to claim 1, further comprising a first outer heat dissipation portion on one principal surface of the ceramic substrate.

7. The ceramic substrate according to claim 6, further comprising a second outer heat dissipation portion on another principal surface of the ceramic substrate.

8. The ceramic substrate according to claim 1, wherein a distance between the heat dissipation portion and the inner wall surface of the housing portion is about 0.5 μm or more and about 200 μm or less.

9. The ceramic substrate according to claim 1, wherein a distance between the heat dissipation portion and the inner wall surface of the housing portion is about 1 μm or more and about 100 μm or less.

10. The ceramic substrate according to claim 1, wherein the housing portion has a rectangular or substantially rectangular shape in plan view.

11. The ceramic substrate according to claim 1, wherein a ratio of a volume of the heat dissipation portion to a capacity of the housing portion is about 90% or more and about 99.998% or less.

12. The ceramic substrate according to claim 1, wherein a thickness of each of the plurality of ceramic layers is about 5 μm or more and about 200 μm or less.

13. The ceramic substrate according to claim 1, wherein a thermal conductivity of the heat dissipation portion is about 100 W/m·K or more and about 2,000 W/m·K or less.

14. The ceramic substrate according to claim 1, wherein a coefficient of linear expansion of the heat dissipation portion is about −1×10⁻⁶/K(m) or more and about 5×10⁻⁶/K(m) or less.

15. The ceramic substrate according to claim 1, further comprising at least one heat dissipation via extending through at least one of the plurality of ceramic layers.

16. The ceramic substrate according to claim 15, wherein the least one heat dissipation via has a thermal conductivity of about 30 W/m·K or more and about 2,000 W/m·K or less.

17. The ceramic substrate according to claim 15, wherein the at least one heat dissipation via includes a thermally conductive particle and a resin.

18. A method for manufacturing a ceramic substrate comprising:
preparing an unfired multilayer body including a ceramic green sheet multilayer body including a plurality of stacked ceramic green sheets and a hole portion in an interior of the multilayer body, and a heat dissipation portion in the hole portion; and
producing a ceramic substrate in which the heat dissipation portion is formed in a housing portion by firing the unfired multilayer body to convert the ceramic green sheet to a ceramic layer and to convert the hole portion to the housing portion; wherein
in the producing the ceramic substrate, firing is performed so that the housing portion formed through the firing has a size in which a first hollow is provided between at least a portion of an outer surface of the heat dissipation portion and an inner wall surface of the housing portion in an extension direction of the heat dissipation portion of the ceramic substrate produced through the firing step.

19. The method for manufacturing a ceramic substrate according to claim 18, wherein a constraining layer including an inorganic material that is substantially not sintered at a temperature of the firing is formed on at least one of outermost layers of the ceramic green sheets in a stacking direction in the unfired multilayer body.
